(19) United States
(12) Patent Application Publication
(10) Pub. No.: US 2026/0043848 A1
(43) Pub. Date: Feb. 12, 2026

(54) CIRCUIT AND METHOD FOR INTERCONNECT TEST

(71) Applicant: Taiwan Semiconductor Manufacturing Company, Ltd., Hsinchu (TW)

(72) Inventors: Mohammed Moiz Khan, San Jose, CA (US); Sandeep K. Goel, Hsinchu City (TW); Yun-Han Lee, Hsinchu City (TW)

(73) Assignee: Taiwan Semiconductor Manufacturing Company, Ltd., Hsinchu (TW)

(21) Appl. No.: 18/950,901

(22) Filed: Nov. 18, 2024

Related U.S. Application Data
(60) Provisional application No. 63/681,447, filed on Aug. 9, 2024.

(51) Int. Cl. G01R 31/317; G01R 31/3185

(52) U.S. Cl. CPC G01R 31/31717; G01R 31/31726; G01R 31/31727; G01R 31/318552

(57) ABSTRACT

A circuit includes a first die including first and second interface circuits, a second die including third and fourth interface circuits, and a first interconnect configured to operatively couple the first die through the first and second interface circuits to the second die through the third and fourth interface circuits. During a first operation stage, the first interface circuit to the fourth interface circuit are each configured to receive control data based on a first frequency, the control data including a series of scan data bits for testing the first interconnect. During a second operation stage following the first operation stage, the first interface circuit to the fourth interface circuit are each configured to receive test data based on a second frequency, the test data including a series of capture data bits for testing the first interconnect. The second frequency is substantially higher than the first frequency.

### CROSS-REFERENCE TO RELATED APPLICATION

This application claims priority to and the benefit of U.S. Provisional Application Number 63/681,447, filed Aug. 9, 2024, entitled “Design-for-Test Method for Die-to-Die Interconnect Delay Test,” which is incorporated herein by reference in its entirety for all purposes.

### BACKGROUND

Multi-die design (e.g., 3-dimensional (3D) integrated circuits (ICs)) may involve stacking multiple dies or chiplets into a single package. The dies may be interconnected through Die-to-Die (D2D) interconnects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an example circuit, in accordance with some embodiments.

FIG. 2 is a block diagram of an example circuit, in accordance with some embodiments.

FIG. 3 is a block diagram of an example circuit, in accordance with some embodiments.

FIG. 4A and FIG. 4B are schematic diagrams of an example circuit, in accordance with some embodiments.

FIG. 5A is a table showing an example implementation of a circuit, in accordance with some embodiments.

FIG. 5B is a table showing an example implementation of a circuit, in accordance with some embodiments.

FIG. 6A, FIG. 6B, FIG. 6C, and FIG. 6D are block diagrams of an example circuit, in accordance with some embodiments.

FIGS. 7A and 7B are block diagrams of an example circuit, in accordance with some embodiments.

FIG. 8A, FIG. 8B and FIG. 8C are schematic diagrams of example circuits in accordance with some embodiments.

FIG. 9A, FIG. 9B, FIG. 9C are schematic diagrams of an example circuit, in accordance with some embodiments.

FIGS. 10A and 10B are block diagrams of an example circuit, in accordance with some embodiments.

FIG. 11 is a flow chart of an example method for operating a circuit, in accordance with some embodiments.

FIG. 12 is a flow chart of an example method for operating a circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, an IC may include multiple dies connected by D2D interconnects. These interconnects need to be tested for various defect types, such as delay tests between the dies. For example, a delay test may include a first die (Die 1) and a second die (Die 2), and the test may be conducted based on a test clock frequency ranging from 10 to 100 MHz. These frequences are typically lower than the IC's functional frequency so as not to indicate the working conditions of the D2D interconnections.

The present disclosure can provide techniques for D2D interconnect testing. During a first operation stage, a first die can be configured to provide control data indicating a test type to a second die based on a first frequency. During a second operation stage following the first operation stage, the first die can be configured to provide test data to the second die based on a second frequency, which is substantially higher than the first frequency. The lower frequency of the first clock reduces the risk of errors or missed control data transmission, while the higher frequency of the second clock accelerates the delay test. In addition, source synchronous clocking mitigates timing issues related to clock synchronization between the two dies. Furthermore, if the second frequency is similar or equal to the functional frequency of the IC, the delay test can more accurately reflect the real working conditions of the D2D interconnections.

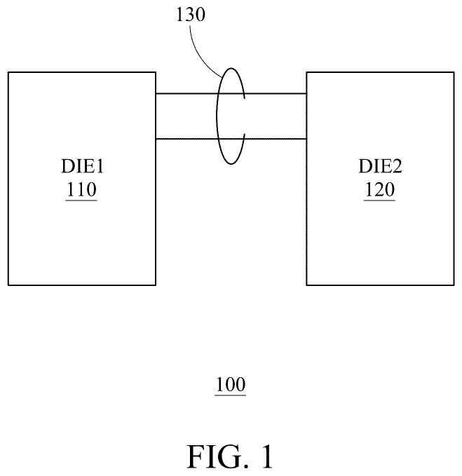

FIG. 1 is a block diagram of an example circuit 100, in accordance with some embodiments. The circuit 100 may be or include an IC D2D interface. For example, the circuit 100 may be a 3D or 2.5D IC interface. The circuit 100 can include a first die 110, a second die 120, and an interconnect 130. Shown in FIG. 1 is a non-limiting example, and the circuit 100 can include more, fewer, or different components than shown in or described with respect to FIG. 1.

In some embodiments, the first die 110 can include a first interface circuit and a second interface circuit. The first interface circuit may be RX/TX1, and the second interface circuit may be TX/RX1. The second die 120 can include a third interface circuit and a fourth interface circuit. The third interface circuit may be TX/RX2, and the fourth interface circuit may be RX/TX2.

In some embodiments, a first interconnect of the interconnect 130 can be configured to operatively couple the first die 110 to the second die 120. The first interconnect of the interconnect 130 can operatively couple the first die 110 through the first and second interface circuits, to the second die 120 through the third and fourth interface circuits. In some embodiments, the first interconnect of the interconnect 130 can be only directed to the interconnection between the first interface circuit and the second interface circuit of the first die 110 and the third interface circuit and the fourth interface circuit of the second die 120.

The first die 110 can be configured to perform a delay test with the second die 120, for example, based on the first interconnect of the interconnect 130. In some examples, the delay test may include a first operation stage and a second operation stage. During the first operation stage, each of the first interface circuit to the fourth interface circuit can be configured to receive control data based on a first frequency (e.g., of a first clock). The control data can include a series of scan data bits for testing the first interconnect of the interconnect 130. During the second operation stage following the first operation stage, each of the first interface circuit to the fourth interface circuit can be configured to receive test data based on a second frequency (e.g., of a second clock) that is substantially higher than the first frequency. In some embodiments, the test data can include a series of capture data bits for testing the first interconnect. In some embodiments, example, the first frequency ranges from 10 to 100 MHz. The second frequency ranges from 1 to 5 GHz and/or substantially similar or equal to the functional frequency of the IC. As the first frequency of the first clock may be lower than the second frequency of the second clock, the risk of errors or missed control data transmission can be reduced. In addition, the higher frequency of the second clock can accelerate the delay test.

In some embodiments, the delay test may include a third operation stage. During the third operation stage, the second die 120 can provide a test result to the first die 110 based on the first clock. The second die 120 can provide the test result according to the delay test type corresponding to the control data and test signal.

In some embodiments, during the first operation stage, the first interface circuit can be configured to receive the control data based on the first frequency. The second interface circuit can be configured to receive the control data through the first interface circuit based on the first frequency. The fourth interface circuit can be configured to receive the control data through a second interconnect from the second interface circuit based on the first frequency. The third interface circuit can be configured to receive the control data through the fourth interface circuit based on the first frequency.

In some embodiments, during the second operation stage, the first interface circuit can be configured to receive the test data based on the second frequency. The second interface circuit can be configured to receive the test data through the first interface circuit based on the second frequency. The fourth interface circuit can be configured to receive the test data through a second interconnect from the second interface circuit based on the second frequency. The third interface circuit can be configured to receive the test data through the fourth interface circuit based on the second frequency.

In some embodiments, the first die 110 (and/or the second die 120) can be configured to determine whether the interconnect has malfunction based on result data. The result data can be provided by the second die 120 (and/or the first die 110) in response to receiving the test data. In some embodiments, at least one of the first die 110 and the second die 120 includes die wrapper register (DWR) circuit to provide the result data and determine whether a particular interconnect has the malfunction.

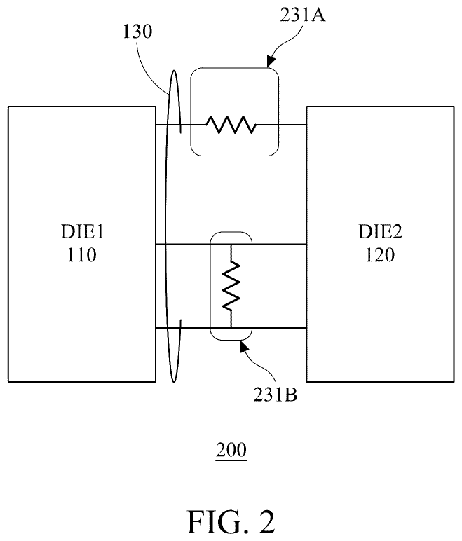

FIG. 2 is a block diagram of an example circuit 200, in accordance with some embodiments. In some embodiments, the circuit 200 may be substantially similar to and/or incorporate features of the circuit 100. For example, the circuit 200 can include the first die 110, the second die 120, the interconnect 130, etc. configured to test a first defect (Resistive Open (high-R)) 231A and a second defect (Resistive Bridge (High-R)) 231B. Shown in FIG. 2 is a non-limiting example, and the circuit 200 can include more, fewer, or different components than shown in or described with respect to FIG. 2.

In some embodiments, the delay test type may be one of defect types including the first defect, Resistive Open (High-R Delay), 231A and the second defect, Resistive Bridge (High-R Delay), 231B. To test the first defect 231A, at-speed transition of 0→1 and of 1→0 can be created at each net. To test the second defect 231B, at-speed transition of 0→1 and of 1→0 can be created at a net, while other nets can be maintained at an opposite constant value.

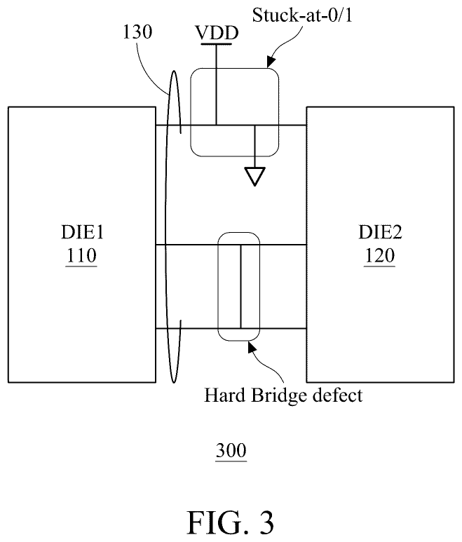

FIG. 3 is a block diagram of an example circuit 300, in accordance with some embodiments. In some embodiments, the circuit 300 may be substantially similar to and/or incorporate features of the circuit 100. For example, the circuit 300 can include the first die 110, the second die 120, the interconnect 130, etc. configured to test a third defect (Stuck-at-0/1) 331C and a fourth defect (Hard Bridge Defect) 331D. Shown in FIG. 3 is a non-limiting example, and the circuit 200 can include more, fewer, or different components than shown in or described with respect to FIG. 3. In some embodiments, the delay test type may be one of defect types including the third defect, Stuck-at-0/1, 331C and the fourth defect, Hard Bridge defect, 331D.

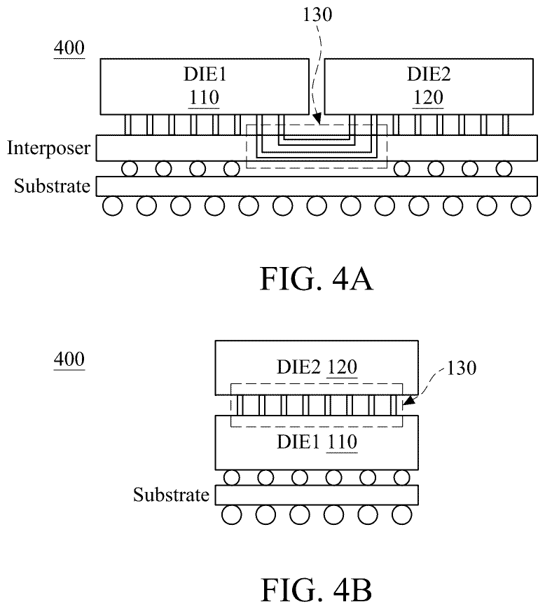

FIG. 4A and FIG. 4B are schematic diagrams of an example circuit 400, in accordance with some embodiments. In some embodiments, the circuit 400 may be substantially similar to and/or incorporate features of the circuit 100. For example, the circuit 400 can include the first die 110, the second die 120, the interconnect 130, etc. while arranged in various manners as shown in FIG. 4A and FIG. 4B. Shown in FIG. 4A and FIG. 4B are non-limiting examples, and the circuit 400 can include more, fewer, or different components than shown in or described with respect to the figures.

As shown in FIG. 4A, in some embodiments, the circuit 400 can be formed such that the first die 110 and the second die 120 can be laterally arranged with respect to each other (2.5D Integration). The circuit 400 can include various features to enable the 2.5D configuration. For example, as shown in FIG. 4A, the interconnect 130 can be formed within an interposer layer, which can be disposed above a substrate.

As shown in FIG. 4B, in some embodiments, the circuit 400 can be formed such that the first die 110 and the second die 120 can be vertically arranged with respect to each other (3D Integration). The circuit 400 can include various features to enable the 3D configuration. For example, as shown in FIG. 4B, the interconnect 130 can be formed between the first die 110 and the second die 120 while the first die 110 and the second die 120 can be formed on the substrate.

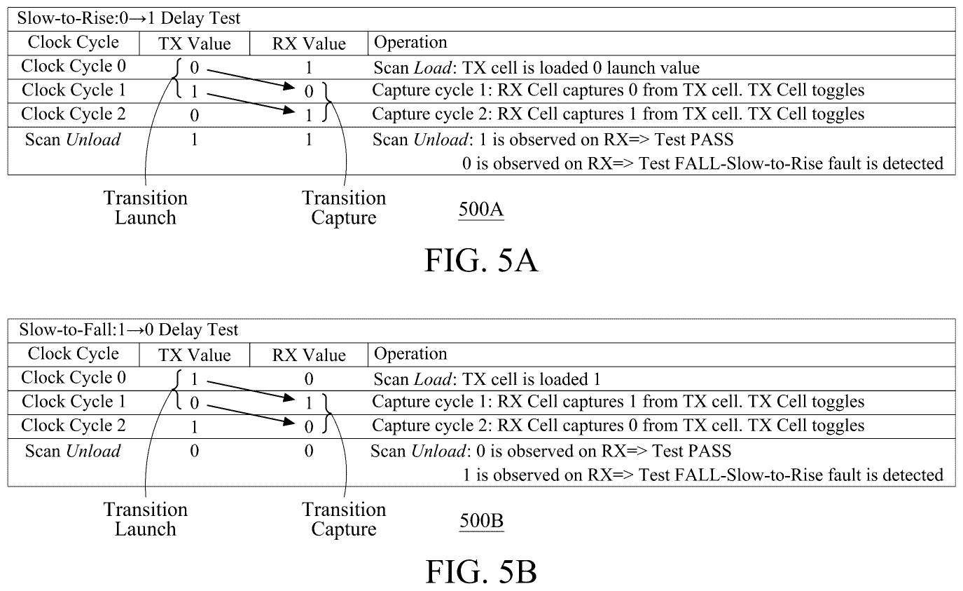

FIG. 5A is a table 500A showing an example implementation of a circuit, in accordance with some embodiments. In some embodiments, the table 500A shows an example implementation of the circuit 100. Shown in FIG. 5A is a non-limiting example, and the implementation in the table 500A can include more, fewer, or different implementations than shown in or described with respect to the figure.

In some embodiments, the circuit 100 can perform “Slow-to-Rise: 0→1 delay test.” The first die 110 can provide control data corresponding to the delay test to the second die 120 during the first operation stage. This can be sometimes referred to as “Scan Load” or “Shift” operation. The second die 120 can receive the control data from the first die 110 and identify that the delay test type is “Slow-to-Rise: 0→1 delay test.” In response to identifying the delay type, the second die 120 can set an RX value to “1” in Clock cycle 0 during the second operation stage.

During the second operation stage, the first die 110 can provide a test signal “0” as a TX value in Clock cycle 0. The first die 110 can provide the test signal “1” in Clock cycle 1. The first die 110 can provide the test signal “0” in Clock cycle 2.

In response to the RX value being “0” in Clock cycle 1 and “1” in Clock cycle 2, the second die 120 can determine that the interconnect 130 passes the delay test. In some embodiments, the second die 120 can provide a “pass” test result during a third operation stage (sometimes referred to as “Scan Unload”), based on the first clock. In response to the RX value being “1” in Clock cycle 1 or “0” in Clock cycle 2, the second die 120 can determine that the interconnect 130 does not pass the delay test. In some embodiments, the second die 120 can provide a “fail” test result during the third operation stage based on the first clock.

FIG. 5B is a table 500B showing an example implementation of a circuit, in accordance with some embodiments. In some embodiments, the table 500B shows an example implementation of the circuit 100. Shown in FIG. 5B is a non-limiting example, and the implementation in the table 500B can include more, fewer, or different implementations than shown in or described with respect to the figure.

In some embodiments, the circuit 100 can perform “Slow-to-Fall: 1→0 delay test.” The first die 110 can provide control data corresponding to the delay test to the second die 120 during the first operation stage. The second die 120 can receive the control data from the first die 110 and identify that the delay test type is “Slow-to-Fall: 0→1 delay test.” In response to identifying the delay type, the second die 120 can set an RX value to “0” in Clock cycle 0 during the second operation stage.

During the second operation stage, the first die 110 can provide a test signal “1” as a TX value in Clock cycle 0. The first die 110 can provide the test signal “0” in Clock cycle 1. The first die 110 can provide the test signal “1” in Clock cycle 2.

In response to the RX value being “1” in Clock cycle 1 and “0” in Clock cycle 2, the second die 120 can determine that the interconnect 130 passes the delay test. In some embodiments, the second die 120 can provide a “pass” test result during the third operation stage based on the first clock. In response to the RX value being “0” in Clock cycle 1 or “1” in Clock cycle 2, the second die 120 can determine that the interconnect 130 does not pass the delay test. In some embodiments, the second die 120 can provide a “fail” test result during the third operation stage based on the first clock.

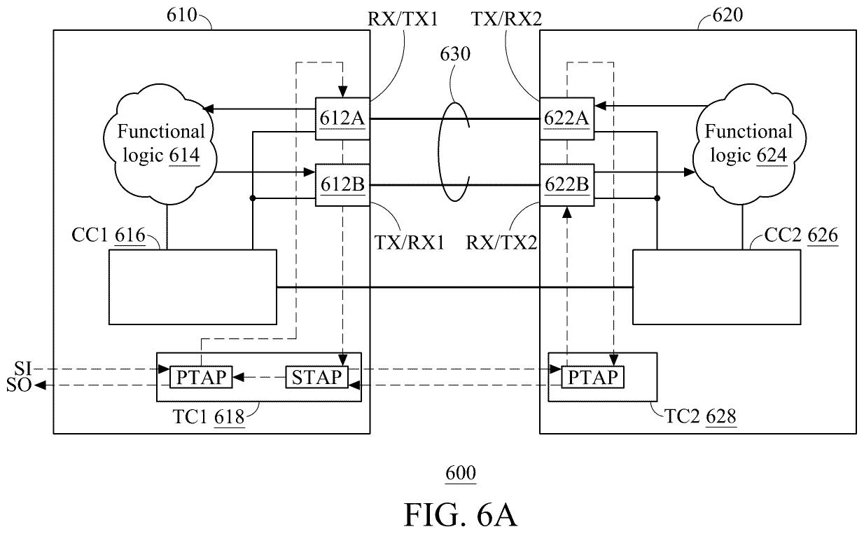

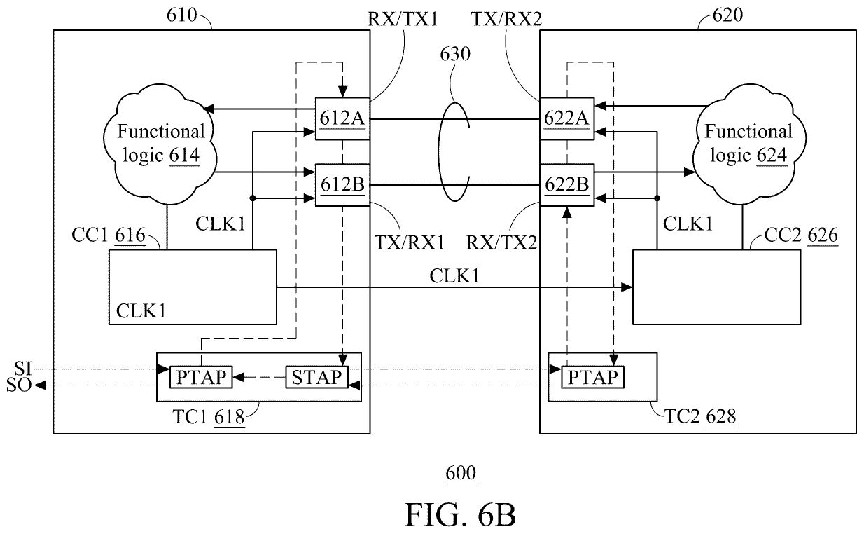

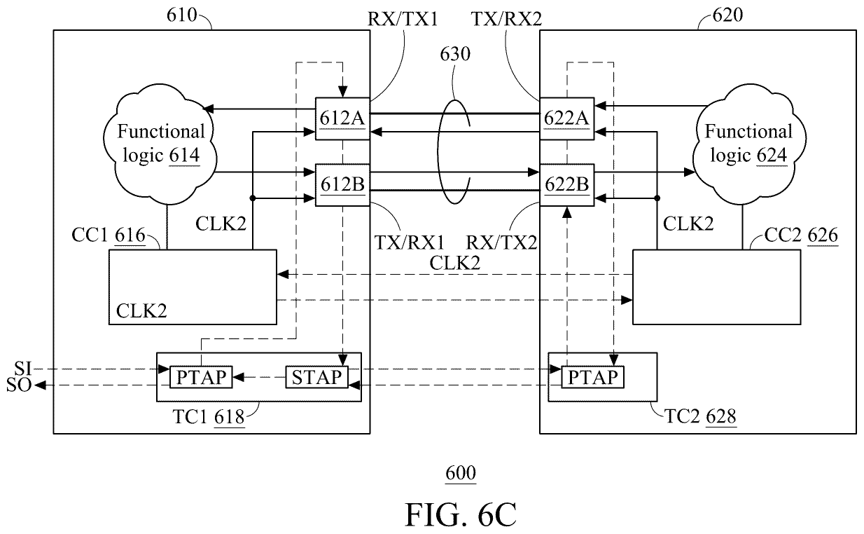

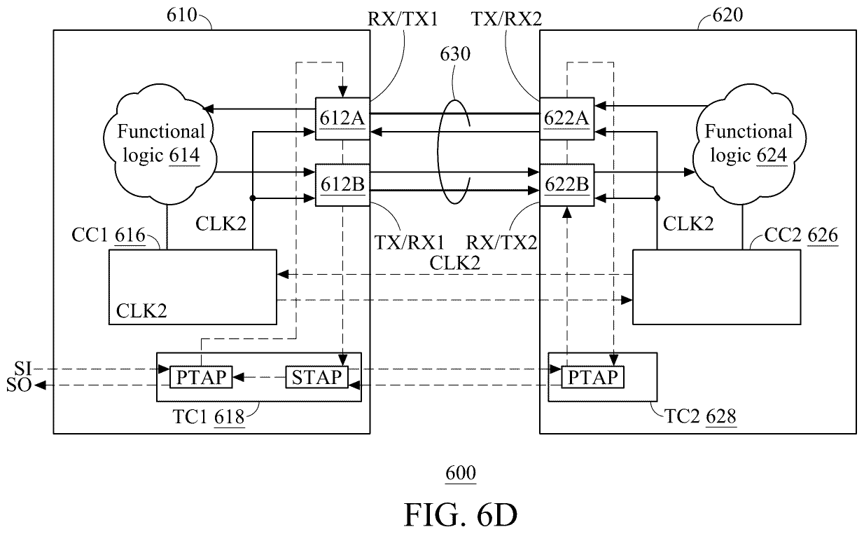

FIG. 6A, FIG. 6B, FIG. 6C, and FIG. 6D are block diagrams of an example circuit 600, in accordance with some embodiments. More specifically, shown in the figures are the circuit 600 during various operation stages. In some embodiments, the circuit 600 may be substantially similar to and/or incorporate features of the circuit 100. For example, the circuit 600 can include a first die 610, a second die 620, and an interconnect 630, which may be substantially similar to and/or incorporate features of the first die 110, the second die 120, and the interconnect 130, respectively. Shown in FIG. 6A, FIG. 6B, FIG. 6C, and FIG. 6D are non-limiting examples, and the circuit 600 can include more, fewer, or different components than shown in or described with respect to FIG. 6A, FIG. 6B, FIG. 6C, and FIG. 6D. In some embodiments, the first die 610 can include a first functional logic (or sometimes referred to as “functional core”) 614, a first clock circuit 616, and a first test signal transmission circuit 618, etc. In some embodiments, the second die 620 can include a second functional logic 624, a second clock circuit 626, and a second test signal transmission circuit 628, etc.

In some embodiments, the first die 610 can include a first interface circuit 612A and a second interface circuit 612B. As shown, the first interface circuit 612A may be RX/TX1, and the second interface circuit 612B may be TX/RX1. The second die 620 can include a third interface circuit 622A and a fourth interface circuit 622B. The third interface circuit 622A may be TX/RX2, and the fourth interface circuit 622B may be RX/TX2.

In some embodiments, a first interconnect of the interconnect 630 can be configured to operatively couple the first die 610 to the second die 620. The first interconnect of the interconnect 630 can operatively couple the first die 610 through the first and second interface circuits 612A, 612B, to the second die 620 through the third and fourth interface circuits 622A, 622B. In some embodiments, the first interconnect of the interconnect 630 can be only directed to the interconnection between the first interface circuit 612A and the second interface circuit 612B of the first die 610 and the third interface circuit 622A and the fourth interface circuit 622B of the second die 620.

As shown, the first clock circuit 616 can be operatively coupled with the first functional logic 614, the first and second interface circuits 612A, 612B, etc. In some embodiments, the first clock circuit 616 can be operatively coupled with the first test signal transmission circuit 618. In some embodiments, the first clock circuit 616 can be operatively coupled with the second clock circuit 626. The first functional logic 614 can be operatively coupled with the first and second interface circuits 612A, 612B. The first and second interface circuits 612A, 612B can be operatively coupled with the first test signal transmission circuit 618.

The second clock circuit 626 can be operatively coupled with the second functional logic 624, the third and fourth interface circuits 622A, 622B, etc. In some embodiments, the second clock circuit 626 can be operatively coupled with the second test signal transmission circuit 628. The second functional logic 624 can be operatively coupled with the third and fourth interface circuits 622A, 622B. The third and fourth interface circuits 622A, 622B can be operatively coupled with the second test signal transmission circuit 628.

Referring to FIG. 6B, during a first operation stage (or referred to as “Scan Load” or “shift” operation), the first clock circuit 616 can provide a first clock (CLK1) having a first frequency (e.g., a lower frequency). The first die 610 and the second die 620 can transmit the first clock CLK1 as shown in the figure. The first clock circuit 616 can provide the first clock CLK1 to the first interface circuit 612A and the second interface circuit 612B, and to the second clock circuit 626. The second clock circuit 626 can provide the first clock CLK1 to the third interface circuit 622A and the fourth interface circuit 622B. This can enable each of the TX/RX interfaces (e.g., the first to fourth interface circuits 612A, 612B, 622A, 622B) to operate based on the first frequency.

Referring to FIG. 6C, during the first operation stage, the first die 610 and the second die 620 can transmit control data (SI) through the TX/RX interfaces (e.g., the first to fourth interface circuits 612A, 612B, 622A, 622B), etc. For example, the first test signal transmission circuit 618 can receive the control data SI and send to the first interface circuit 612A. The first interface circuit 612A can send the control data SI to the second interface circuit 612B, which can send the control data SI to the first test signal transmission circuit 618. The first test signal transmission circuit 618 can send the control data SI to the second test signal transmission circuit 628, which can send the control data SI to the fourth interface circuit 622B. The fourth interface circuit 622B can receive the control data SI and send to the third interface circuit 622A, which can send the control data SI to the second test signal transmission circuit 628. The second test signal transmission circuit 628 can send the control data SI to the first test signal transmission circuit 618. This enables the second die 620 to receive the control data SI based on the first frequency and obtain the delay test type based on the control data SI.

Still referring to FIG. 6C, during a second operation stage (or sometimes referred to as “capture” operation), the first clock circuit 616 can provide a second clock (CLK2) having a second frequency (e.g., a higher frequency). The first die 610 and the second die 620 can transmit the second clock CLK2 as shown in the figure. The first clock circuit 616 can provide the second clock CLK2 to the first interface circuit 612A and the second interface circuit 612B, and to the second clock circuit 626. The second clock circuit 626 can provide the second clock CLK2 to the third interface circuit 622A and the fourth interface circuit 622B. In some embodiments, the first clock circuit 616 and the second clock circuit 626 can be configured to send the second clock CLK2 to the second clock circuit 626 and the first clock signal 616, respectively. In some embodiments, during the second stage, one of the first clock circuit 616 and the second clock circuit 626 can send the second clock CLK2 to the other clock circuit. For example, during the second stage, the first clock circuit 616 can send the second clock CLK2 to the second clock circuit 626. During the second stage, the second clock circuit 626 can send the second clock CLK2 to the first clock circuit 616. This can enable each of the TX/RX interfaces (e.g., the first to fourth interface circuits 612A, 612B, 622A, 622B) to operate based on the second frequency.

Referring to FIG. 6D, during the second operation stage, in response to the first clock circuit 616 providing the second clock CLK2 having the second frequency, the TX/RX interfaces (e.g., the first to fourth interface circuits 612A, 612B, 622A, 622B) can generate the test signal based on the second clock CLK2, for example, as discussed with respect to FIG. 5A and FIG. 5B.

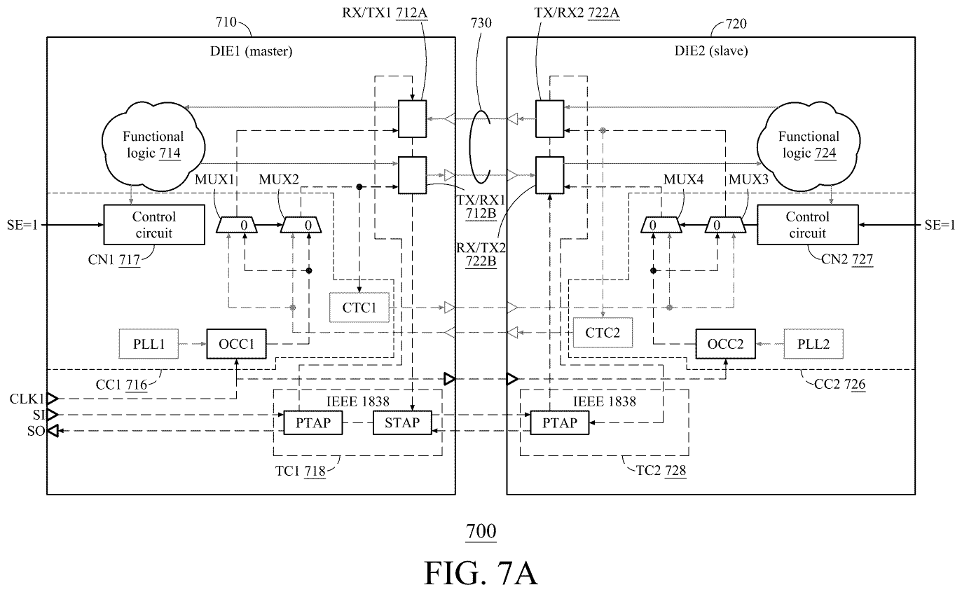

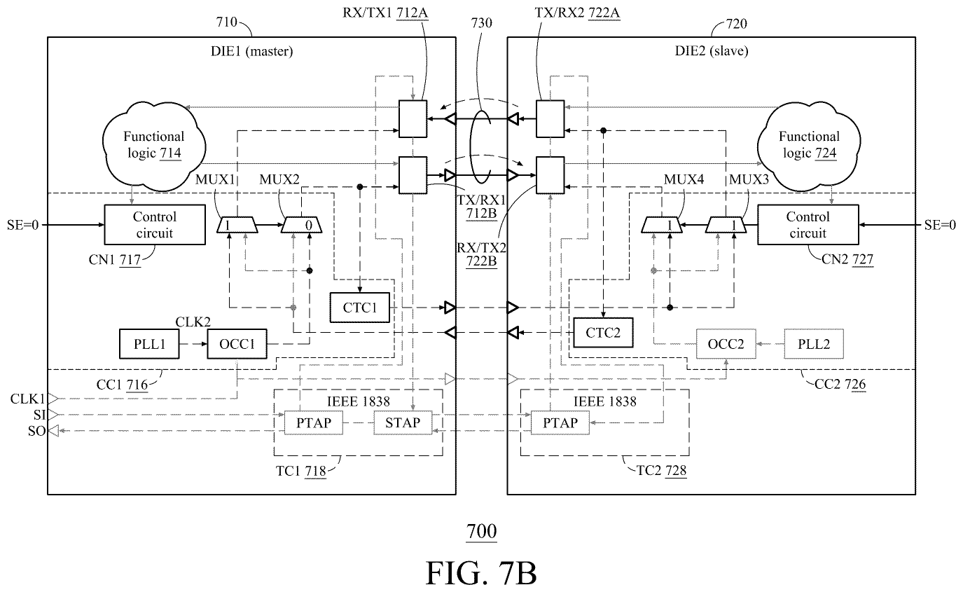

FIGS. 7A and 7B are block diagrams of an example circuit 700, in accordance with some embodiments. More specifically, shown in the figures are the circuit 700 during various operation stages. In some embodiments, the circuit 700 may be substantially similar to and/or incorporate features of the circuit 100. For example, the circuit 700 can include a first die 710, a second die 720, and an interconnect 730, which may be substantially similar to and/or incorporate features of the first die 110, the second die 120, and the interconnect 130, respectively. Shown in FIG. 7A and FIG. 7B are non-limiting examples, and the circuit 700 can include more, fewer, or different components than shown in or described with respect to FIG. 7A and FIG. 7B. In some embodiments, the first die 710 can include a first functional logic 714, a first clock circuit 716, a first control circuit 717, and a first test signal transmission circuit 718, etc. In some embodiments, the second die 720 can include a second functional logic 724, a second clock circuit 726, a second control circuit 727, and a second test signal transmission circuit 728, etc.

In some embodiments, the first die 710 can include a first interface circuit 712A and a second interface circuit 712B. As shown, the first interface circuit 712A may be RX/TX1, and the second interface circuit 712B may be TX/RX1. The second die 720 can include a third interface circuit 722A and a fourth interface circuit 722B. The third interface circuit 722A may be TX/RX2, and the fourth interface circuit 722B may be RX/TX2.

In some embodiments, the first clock circuit 716 can include the first control circuit 717, a first multiplexer (MUX1), a second multiplexer (MUX2), a first phase-locked loop (PLL1), a first open-loop control circuit (OCC1), and a first clock transmission circuit (CTC1). The second clock circuit 726 can include the second control circuit 727, a third multiplexer (MUX3), a fourth multiplexer (MUX4), a second phase-locked loop (PLL2), a second open-loop control circuit (OCC2), and a clock transmission circuit (CTC2).

In some embodiments, during a first operation stage, the MUX1 and the MUX2 can be configured to select a first clock with a first clock frequency and provide the first clock to the first interface circuit 712A and the second interface circuit 712B, respectively. The MUX3 and the MUX4 can be configured to select the first clock with the first clock frequency and provide the first clock to the third interface circuit 722A and the fourth interface circuit 722B, respectively.

In some embodiments, during the second operation stage, the MUX2 can be configured to select a second clock with a second clock frequency and provide the second clock to the second interface circuit 712B then to the fourth interface circuit 722B (e.g., through a first interconnect of the interconnect 730). The MUX3 can be configured to select the second clock received (e.g., through a second interconnect of the interconnect 730) and provide the second clock to the third interface circuit 722A then to the first interface circuit 712A (e.g., through the first interconnect). The MUX4 can be configured to select the second clock received (e.g., through the second interconnect) and provide the second clock to the fourth interface circuit 722B.

In some embodiments, the MUX1 and the MUX2 can be configured to select the first clock signal based on a first control signal, configured at a first logic state, and the MUX3 and the MUX4 can be configured to select the first clock signal based on a second control signal, configured at the first logic state. In some embodiments, the MUX1 and the MUX2 can be configured to select the second clock signal based on the first control signal, configured at a second logic state, and the MUX3 and the MUX4 can be configured to select the second clock signal based on the second control signal, configured at the second logic state.

For example, referring to FIG. 7A, during a first stage, the PLL1, the PLL2, the CTC1 and the CTC2 can be disabled. The OCC1 can receive a first clock (CLK1), and the first clock circuit 716 can receive a signal SE of “1.” The first control circuit 716 can control the MUX1 to output the first clock (CLK1) to the first interface circuit 712A (e.g., RX/TX1) and control the MUX2 to output the first clock (CLK1) to the second interface circuit 712B (e.g., TX/RX1) in response to receiving at least the signal SE of “1.” During the first stage, the OCC2 can receive the first clock (CLK1). The second clock circuit 726 can receive a signal SE of “1.” The second control circuit 726 can control the MUX3 to output the first clock (CLK1) to the third interface circuit 722A (e.g., TX/RX2) and control the MUX4 to output the first clock (CLK1) to the fourth interface circuit 722B (e.g., RX/TX2) in response to receiving at least the signal SE of “1.”

For example, referring to FIG. 7B, during a second stage, the PLL1 can be enabled to generate a second clock (CLK2). The OCC1 can receive the second clock (CLK2). The first clock circuit 716 can receive a signal SE of “0.” The first control circuit 717 can control the MUX2 to output the second clock (CLK2) to the first and second interface circuits 712A, 712B and to the CTC1 in response to receiving at least the signal SE of “0.” In some embodiments, during the second stage, the CTC1 can be enabled to transmit the second clock (CLK2) to the MUX3 and MUX4. The second control circuit 727 can control the MUX3 to output the second clock (CLK2) to the first and third interface circuits 712A, 722A and to the CTC2 and can control the MUX4 to output the second clock (CLK2) to the fourth interface circuit 722B in response to receiving at least the signal SE of “0.” In some embodiments, during the second stage, the CTC1 can be enabled to transmit the second clock (CLK2) to the MUX1. The first control circuit 717 can control the MUX1 to output the second clock (CLK2) to the first interface circuit 712A in response to receiving at least the signal SE of “0.” Therefore, each of the first to fourth interface circuits 712A, 712B, 722A, 722B can receive the second clock (CLK2). This can thereby mitigate timing issues with clock synchronization between two dies.

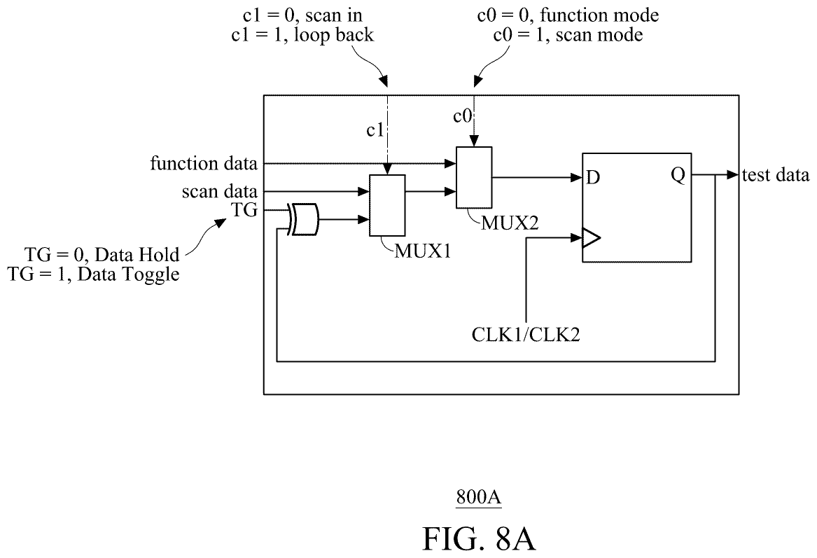

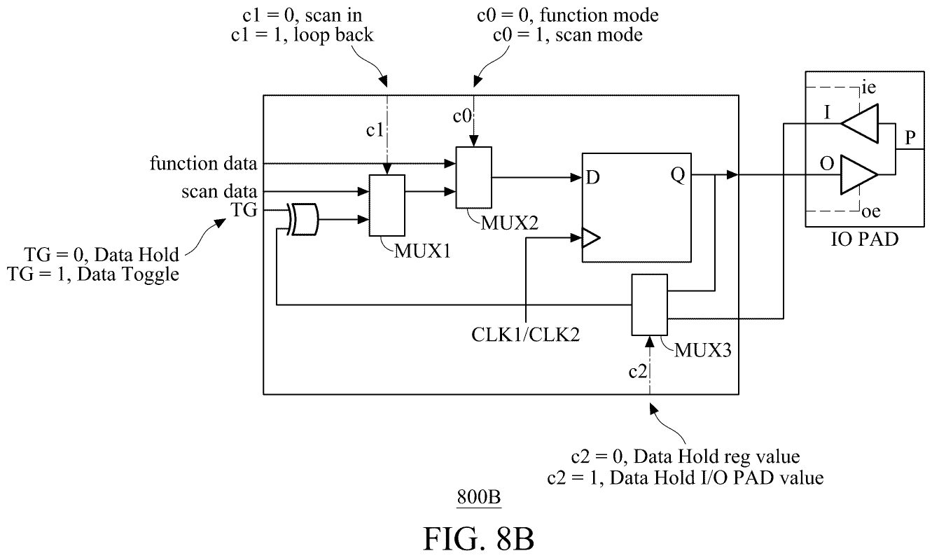

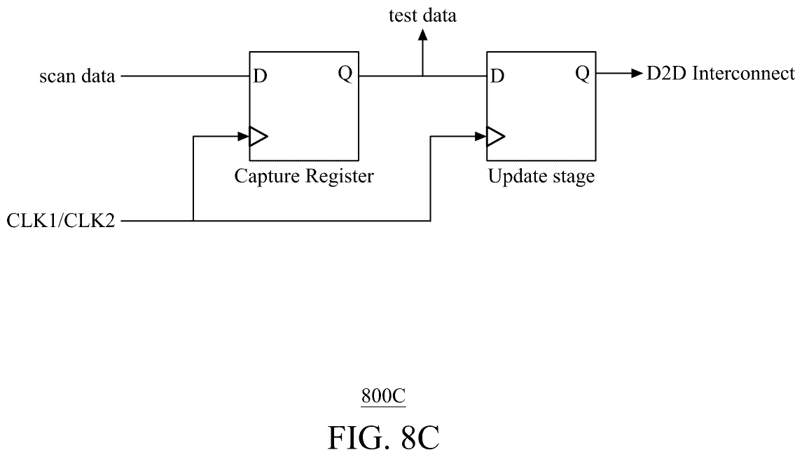

FIG. 8A, FIG. 8B and FIG. 8C are schematic diagrams of example circuits 800A, 800B, 800C in accordance with some embodiments. In some embodiments, the circuits 800A, 800B, 800C may be part of the circuits 100, 600, 700, etc. For example, the circuits 800A, 800B, 800C can be included in an interface circuit (e.g., the interface circuits RX/TX, TX/RX, etc.). In some embodiments, the circuits 800A, 800B, 800C may be a die wrapper register (DWR) circuit. Shown in FIG. 8A, FIG. 8B, and FIG. 8C are non-limiting examples, and the circuits 800A, 800B, 800C can include more, fewer, or different components than shown in or described with respect to the figures.

Referring to FIG. 8A, during a second stage, a first multiplexer (MUX1) can receive a signal c1 of “0” and a second multiplexer (MUX2) can receive a signal c0 of “1.” The circuit 800A can generate test data in response to receiving scan data and a clock CLK1/CLK2. In some embodiments, the circuit 800A can generate the test data in response to receiving functional data. Referring to FIG. 8B, the circuit 800B can additionally include a third multiplexer (MUX3). During the second stage, the MUX1 can receive the signal c1 of “0,” the MUX2 can receive the signal c0 of “1,” and the MUX3 can receive a signal c2 of “1.” The circuit 800B can generate the test data and output to an interface circuit (e.g., RX/TX, TX/RX, etc.) in response to receiving the scan data and the clock CLK1/CLK2. In some embodiments, the circuit 800B can generate the test data in response to receiving functional data. Referring to FIG. 8C, during the second stage, the circuit 800C can generate the test data and output to the interface circuit (e.g., RX/TX, TX/RX, etc.) in response to receiving the scan data and the second clock CLK2.

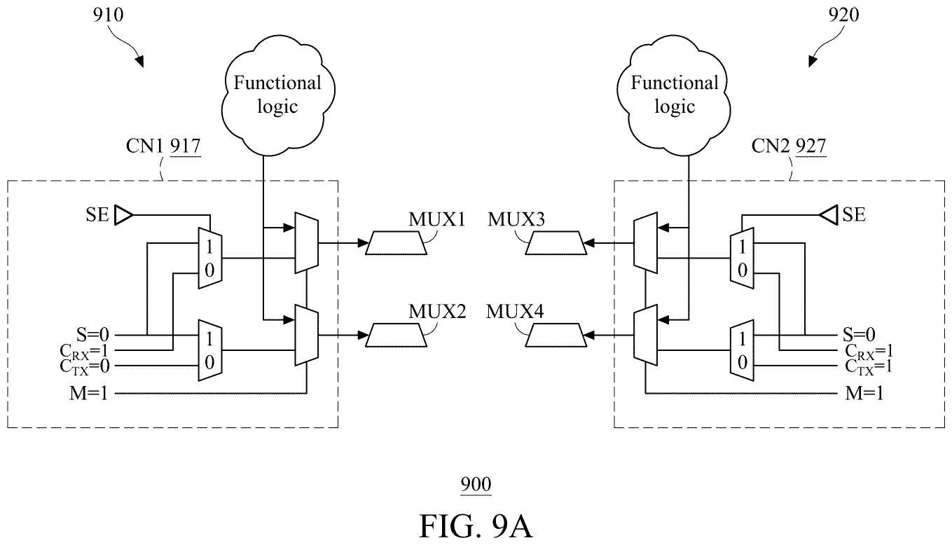

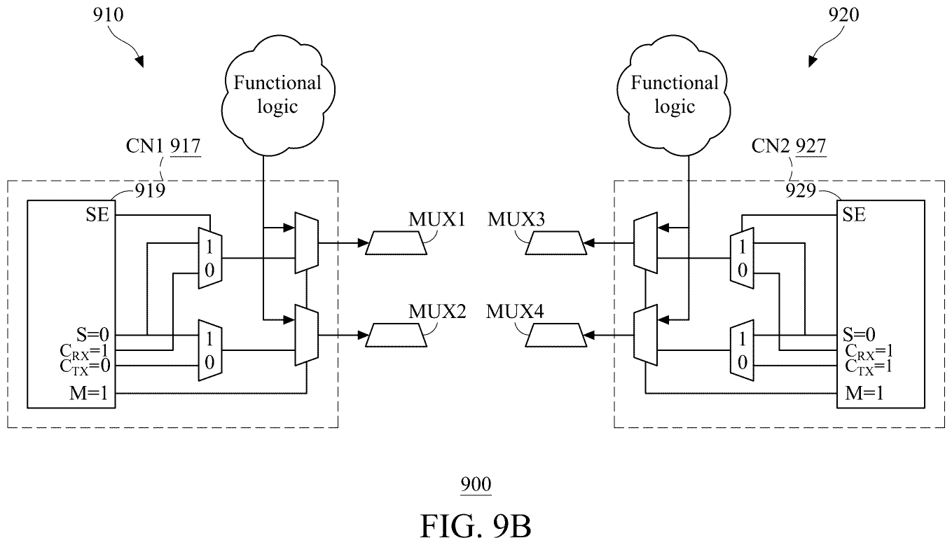

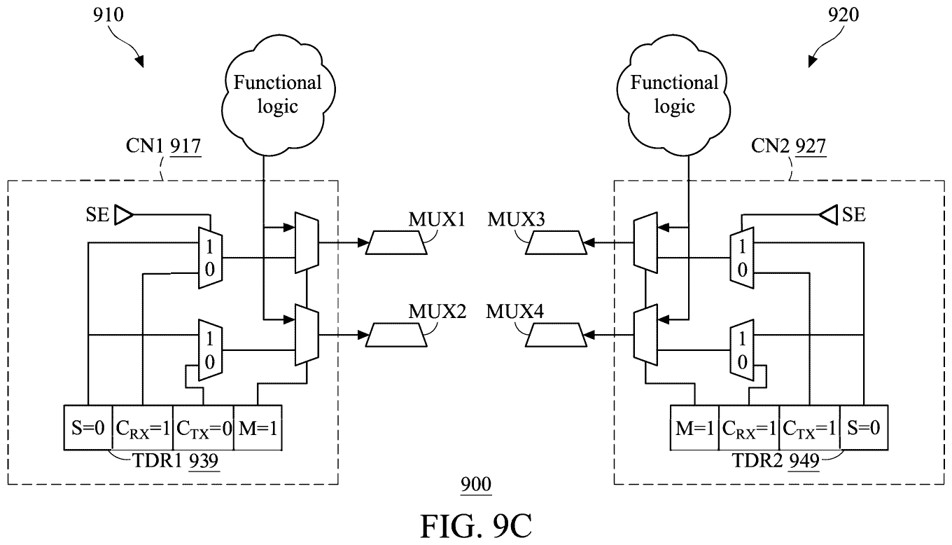

FIG. 9A, FIG. 9B, FIG. 9C are schematic diagrams of an example circuit 900, in accordance with some embodiments. In some embodiments, the circuit 900 may be substantially similar to and/or incorporate features of the circuit 100. For example, the circuit 900 can include a first die 910, a second die 920, etc., which may be substantially similar to and/or incorporate features of the first die 110, the second die 120, etc., respectively. Shown in FIG. 9A, FIG. 9B, FIG. 9C are non-limiting examples, and the circuit 900 can include more, fewer, or different components than shown in or described with respect to the figures. In some embodiments, the first die 910 can include a first control circuit 917, a first multiplexer (MUX1), and a second multiplexer (MUX2). The second die 920 can include a second control circuit 927, a third multiplexer (MUX3), and a fourth multiplexer (MUX4).

In some embodiments, referring to FIG. 9A, state data (e.g., S, CRX, CTX, M) may be external data. The state data (e.g., S, CRX, CTX, M) can be applied in various manners. In some embodiments, the state data may be control values used to apply correct select signals for MUX1, MUX2, MUX3, MUX4. These control values can be applied based on primary inputs (PIs), test data registers (TDRs), a Finite State machine that can generate these signals, etc. This allows first operation and second operation stages of a delay test of the circuit 400 to be performed by a “Primary Input (PI) Control.” The state data can be used to control the multiplexers MUX1, MUX2, MUX3, MUX4. Referring to FIG. 9B, in some embodiments, the state data and signal SE may be provided by a Finite State Machine (FSM). For example, as opposed to the circuit 900 shown in FIG. 9A, the circuit 900 shown in FIG. 9B can include the FSMs. The first die 910 can include a first FSM 919. The second die 920 can include a second FSM 929. The first and second FSMs 919, 929 can provide the state data and signal SE. Referring to FIG. 9C, the first die 910 of the circuit 900 can additionally include a first test data register (TDR) 919, and the second die 920 of the circuit 900 can include a second TDR 929. For example, the first control circuit 917 can include the first control circuit 917 can include the first TDR 919, and the second control circuit 927 can include the second TDR 929. In some embodiments, each of the first TDR 919 and the second TDR 929 can include the state data. In some embodiments, the first TDR 919 and second TDR 929 may be omitted.

Still referring to FIG. 9C, in some embodiments, the state data can be used to control the multiplexers MUX1, MUX2, MUX3, MUX4. In the first TDR 919, the state data S can be set to “0,” the state data CRX can be set to “1,” the state data CTX can be set to “0,” and the state data M can be set to “1.” In the second TDR 929, the state data S can be set to “0,” the state data CRX can be set to “1,” the state data CTX can be set to “1,” and the state data M can be set to “1.”

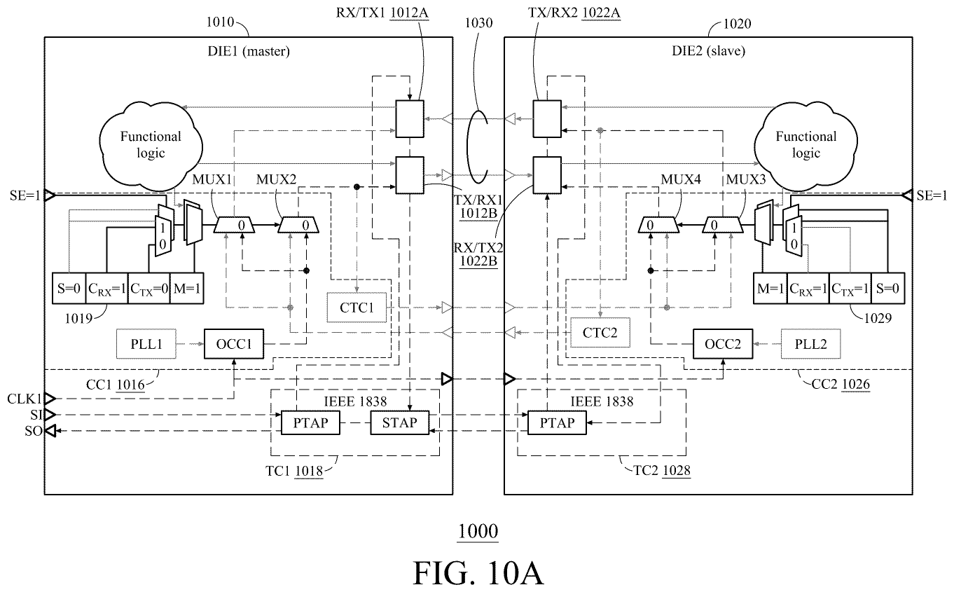

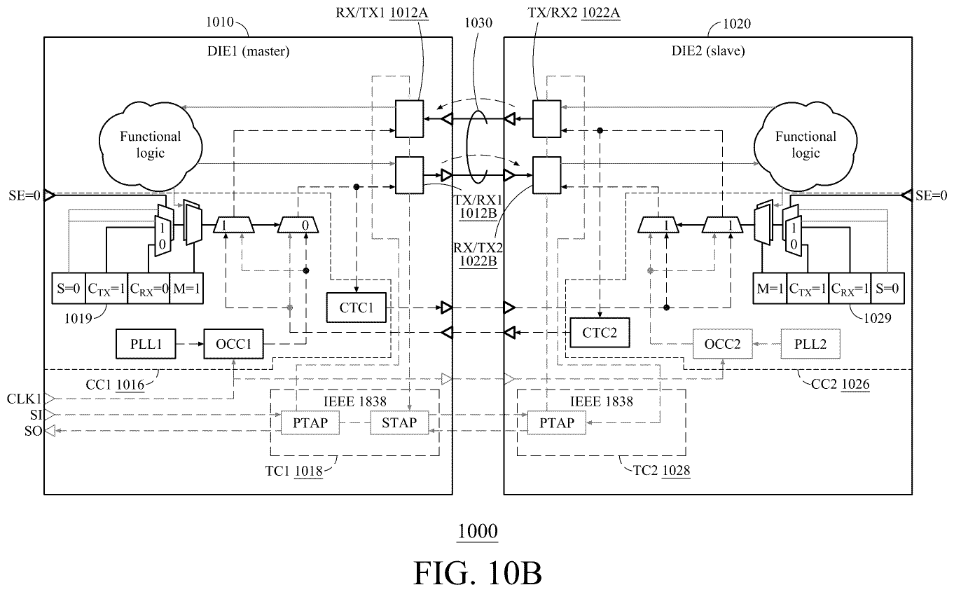

FIGS. 10A and 10B are block diagrams of an example circuit 1000, in accordance with some embodiments. More specifically, shown in the figures are the circuit 1000 during various operation stages. In some embodiments, the circuit 1000 may be substantially similar to and/or incorporate features of the circuit 100. For example, the circuit 1000 can include a first die 1010, a second die 1020, and an interconnect 1030, which may be substantially similar to and/or incorporate features of the first die 110, the second die 120, and the interconnect 130, respectively. Shown in FIG. 10A and FIG. 10B are non-limiting examples, and the circuit 1000 can include more, fewer, or different components than shown in or described with respect to FIG. 10A and FIG. 10B. In some embodiments, the first die 1010 can include a first clock circuit 1016, a first TDR 1019, and a first test signal transmission circuit 1018, etc. In some embodiments, the second die 1020 can include a second clock circuit 1026, a second TDR 1029, and a second test signal transmission circuit 1028, etc.

In some embodiments, the first die 1010 can include a first interface circuit 1012A and a second interface circuit 1012B. As shown, the first interface circuit 1012A may be RX/TX1, and the second interface circuit 1012B may be TX/RX1. The second die 1020 can include a third interface circuit 1022A and a fourth interface circuit 1022B. The third interface circuit 1022A may be TX/RX2, and the fourth interface circuit 1022B may be RX/TX2.

As shown, the circuit 1000 can operate based on the first and second TDRs 1019, 1029. In some embodiments, referring to FIG. 10A, during a first stage, based on a signal SE of “1” and state data M of “1,” the first control circuit (CN1) 1016 can control the MUX1 to output a first clock (CLK1) to the first interface circuit 1012A (e.g., RX/TX1) and control the MUX2 to output the first clock (CLK1) to the second interface circuit 1012B (e.g., TX/RX1). The second control circuit 1026 can control the MUX3 to output the first clock (CLK1) to the third interface circuit 1022A (e.g., TX/RX2) and control the MUX4 to output the first clock (CLK1) to the fourth interface 1022B (e.g., RX/TX2). Referring to FIG. 10B, during a second stage, based on the signal SE of “0” and the state data M of “1,” the first control circuit 1016 can control the MUX2 to output the second clock (CLK2) to the second and fourth interface circuits 1012B, 1022B (e.g., TX/RX1, RX/TX2) and a first clock transmission circuit (CTC1), and control the MUX1 to output the second clock (CLK2) to the first interface circuit 1012A (e.g., RX/TX1). The second control circuit 1026 cam control the MUX3 to output the second clock (CLK2) to the first and third interface circuits 1012A, 1022A (e.g., TX/RX2, RX/TX1) and a second clock transmission circuit (CTC2) and control the MUX4 to output the second clock (CLK2) to the fourth interface circuit (e.g., RX/TX2).

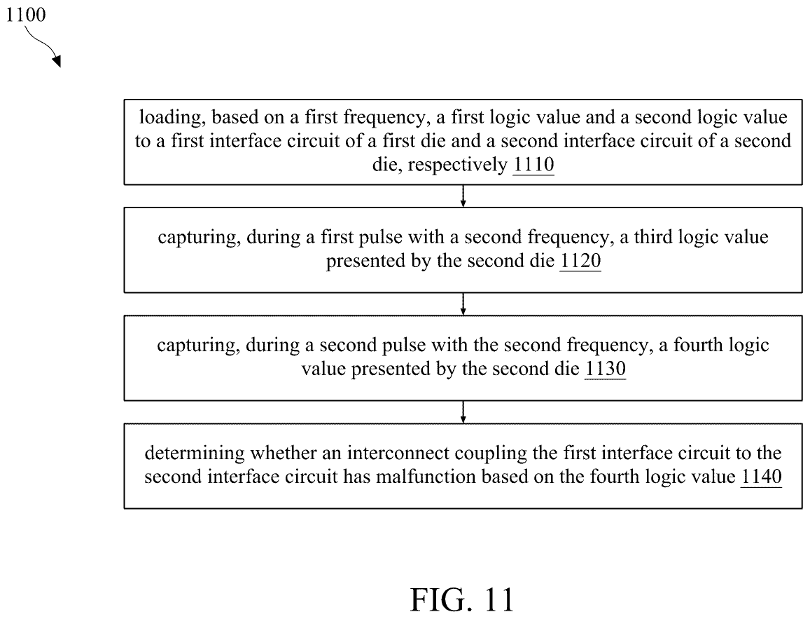

FIG. 11 is a flow chart of an example method 1100 for operating a circuit, in accordance with some embodiments. The method 1100 may be performed by one or more components of the circuits 100, 600, 700, 1000, etc. In some embodiments, the method 1100 can be performed by other entities. In some embodiments, the method 1100 includes more, fewer, or different operations than shown in FIG. 11.

In a brief overview, the method 1100 can start with operation 1110 of loading, based on a first frequency, a first logic value and a second logic value to a first interface circuit of a first die and a second interface circuit of a second die, respectively. The method 1100 can continue to operation 1120 of capturing, during a first pulse with a second frequency, a third logic value presented by the second die. The method 1100 can continue to operation 1120 of capturing, during a second pulse with the second frequency, a fourth logic value presented by the second die. The method 1100 can continue to operation 1120 of determining whether an interconnect coupling the first interface circuit to the second interface circuit has malfunction based on the fourth logic value.

At operation 1110, a first logic value and a second logic value can be loaded to a first interface circuit (e.g., the first interface circuit 612A, etc.) of a first die (e.g., the first die 610, etc.) and a second interface circuit (e.g., the third interface circuit 622A, etc.) of a second die (e.g., the second die 620, etc.), based on a first frequency. In some embodiments, the first die and the second die can be laterally arranged with respect to each other. For example, the first die and the second die can be arranged with 2.5D configuration. In some embodiments, the first die and the second die can be vertically arranged with respect to each other. For example, the first die and the second die can be arranged with 3D configuration. At operation 1120, during a first pulse with a second frequency, a third logic value presented by the second die can be captured. At operation 1130, during a second pulse with the second frequency, a fourth logic value presented by the second die can be captured. At operation 1140, whether an interconnect (e.g., the interconnect 130) coupling the first interface circuit to the second interface circuit has malfunction can be determined based on the fourth logic value.

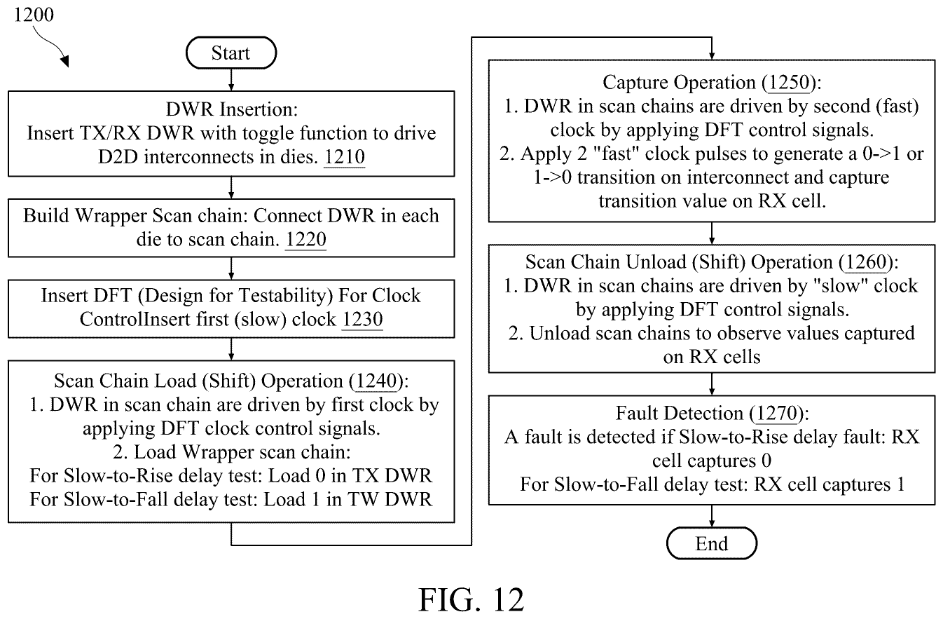

FIG. 12 is a flow chart of an example method 1200 for operating a circuit, in accordance with some embodiments. The method 1200 may be performed by one or more components of the circuits 100, 600, 700, 1000, etc. In some embodiments, the method 1200 can be performed by other entities. In some embodiments, the method 1200 includes more, fewer, or different operations than shown in FIG. 12.

In a brief overview, the method 1200 can start with operation 1210 of performing die wrapper register (DWR) insertion. The method 1200 can continue to operation 1220 of building wrapper scan chain. The method 1200 can continue to operation 1230 of inserting design for testability (DFT) for clock control.

The method 1200 can continue to operation 1240 of performing scan chain load (shift) operation. The method 1200 can continue to operation 1250 of performing capture operation. The method 1200 can continue to operation 1260 of performing scan chain unload (shift) operation. The method 1200 can continue to operation 1270 of performing fault detection. In some embodiments, operation 1230 to operation 1240 can be performed during a first operation stage of a circuit. In some embodiments, operation 1250 can be performed during a second operation stage of the circuit. In some embodiments, operation 1260 to operation 1270 can be performed during a third operation stage of the circuit.

At operation 1210, the DWR insertion can be performed. TX/RX DWR can be inserted with a toggle function to drive interface circuits (e.g., the first to fourth interface circuits 612A, 612B, 622A, 622B) in dies (e.g., the first and second dies 610, 620). At operation 1220, the wrapper scan chain can be built by connecting the DWR in each die to scan the chain. At operation 1230, the DFT for clock control can be inserted, and a first clock (e.g., having a lower frequency) can be inserted. At operation 1240, the scan chain load (shift) operation can be performed. The DWR in the scan chain can be driven by the first clock by applying the DFT clock control signals. The wrapper scan chain can then be loaded. For a slow-to-rise delay test, a logic state of “0” can be loaded in TX DWR. For a slow-to-fall delay test, a logic state of “1” can be loaded in TW DWR. At operation 1250, the capture operation can be performed. DWR in the scan chain can be driven by a second clock (e.g., having a higher frequency) by applying the DFT control signals. In some embodiments, two clock pulses having the higher frequency can be applied to generate a 0→1 or 1→0 transition on the interconnect, and the transition value can be captured on an RX cell. At operation 1260, the scan chain unload (shift) operation can be performed. The DWR in the scan chains can be driven by the first clock (e.g., having the lower frequency) by applying the DFT control signals. The scan chains can be unloaded to observe the values captured on the RX cells. At operation 1270, the fault detection can be performed. In some embodiments, a slow-to-rise delay fault can be detected if the RX cell captures “0.” In some embodiments, a slow-to-fall delay fault can be detected if the RX cell captures “1.”

In one aspect of the present disclosure, a circuit is disclosed. The circuit includes a first die including a first interface circuit and a second interface circuit, a second die including a third interface circuit and a fourth interface circuit, and a first interconnect configured to operatively couple the first die through the first and second interface circuits to the second die through the third and fourth interface circuits. During a first operation stage, the first interface circuit to the fourth interface circuit are each configured to receive control data based on a first frequency, the control data including a series of scan data bits for testing the first interconnect. During a second operation stage following the first operation stage, the first interface circuit to the fourth interface circuit are each configured to receive test data based on a second frequency, the test data including a series of capture data bits for testing the first interconnect. The second frequency is substantially higher than the first frequency

In another aspect of the present disclosure, a circuit is disclosed. The circuit includes a first die, a second die, and at least one interconnect configured to operatively couple the first die to the second die. During a first operation stage, the first die is configured to provide control data indicating a test type to the second die based on a first frequency. During a second operation stage following the first operation stage, the first die is configured to provide test data to the second die based on a second frequency, the second frequency being substantially higher than the first frequency.

In yet another aspect of the present disclosure, a method is disclosed. The method includes loading, based on a first frequency, a first logic value and a second logic value to a first interface circuit of a first die and a second interface circuit of a second die, respectively, capturing, during a first pulse with a second frequency, a third logic value presented by the second die, capturing, during a second pulse with the second frequency, a fourth logic value presented by the second die, and determining whether an interconnect coupling the first interface circuit to the second interface circuit has malfunction based on the fourth logic value. The second frequency is substantially higher than the first frequency.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a first die including a first interface circuit and a second interface circuit;
a second die including a third interface circuit and a fourth interface circuit; and
a first interconnect configured to operatively couple the first die through the first interface circuit and the second interface circuit to the second die through the third interface circuit and the fourth interface circuit;
wherein, during a first operation stage, the first interface circuit to the fourth interface circuit are each configured to receive control data based on a first frequency, the control data including a series of scan data bits for testing the first interconnect;
wherein, during a second operation stage following the first operation stage, the first interface circuit to the fourth interface circuit are each configured to receive test data based on a second frequency, the test data including a series of capture data bits for testing the first interconnect; and
wherein the second frequency is substantially higher than the first frequency.

2. The circuit of claim 1, wherein, during the first operation stage, the first interface circuit is configured to receive the control data based on the first frequency, the second interface circuit is configured to receive the control data through the first interface circuit based on the first frequency, the fourth interface circuit is configured to receive the control data through a second interconnect from the second interface circuit based on the first frequency, and the third interface circuit is configured to receive the control data through the fourth interface circuit based on the first frequency.

3. The circuit of claim 1, wherein, during the second operation stage, the first interface circuit is configured to receive the test data based on the second frequency, the second interface circuit is configured to receive the test data through the first interface circuit based on the second frequency, the fourth interface circuit is configured to receive the test data through a second interconnect from the second interface circuit based on the second frequency, and the third interface circuit is configured to receive the test data through the fourth interface circuit based on the second frequency.

4. The circuit of claim 1, wherein the first die is configured to determine whether the first interconnect has malfunction based on result data, and wherein the result data is provided by the second die in response to receiving the test data.

5. The circuit of claim 1, wherein the first die comprises a first multiplexer and a second multiplexer, and the second die comprises a third multiplexer and a fourth multiplexer.

6. The circuit of claim 5, wherein, during the first operation stage, the first multiplexer and the second multiplexer are configured to select a first clock with a first clock frequency and provide the first clock to the first interface circuit and the second interface circuit, respectively, and the third multiplexer and the fourth multiplexer are configured to select the first clock with the first clock frequency and provide the first clock to the third interface circuit and the fourth interface circuit, respectively.

7. The circuit of claim 6, wherein, during the second operation stage, the second multiplexer is configured to select a second clock with a second clock frequency and provide the second clock to the second interface circuit then to the fourth interface circuit through the first interconnect, the third multiplexer is configured to select the second clock received through a second interconnect and provide the second clock to the third interface circuit then to the first interface circuit through the first interconnect, and the fourth multiplexer is configured to select the second clock received also through the second interconnect and provide the second clock to the fourth interface circuit.

8. The circuit of claim 7, wherein the first multiplexer and the second multiplexer are configured to select a first clock signal based on a first control signal, configured at a first logic state, and the third multiplexer and the fourth multiplexer are configured to select the first clock signal based on a second control signal, configured at the first logic state.

9. The circuit of claim 8, wherein the first multiplexer and the second multiplexer are configured to select a second clock signal based on the first control signal, configured at a second logic state, and the third multiplexer and the fourth multiplexer are configured to select the second clock signal based on the second control signal, configured at the second logic state.

10. The circuit of claim 1, wherein the first die and the second die are laterally arranged with respect to each other.

11. The circuit of claim 1, wherein the first die and the second die are vertically arranged with respect to each other.

12. A circuit, comprising:
a first die;
a second die; and
at least one interconnect configured to operatively couple the first die to the second die;
wherein, during a first operation stage, the first die is configured to provide control data indicating a test type to the second die based on a first frequency;
wherein, during a second operation stage following the first operation stage, the first die is configured to provide test data to the second die based on a second frequency, the second frequency being substantially higher than the first frequency.

13. The circuit of claim 12, wherein the first die is configured to determine whether the at least one interconnect has malfunction based on result data, and wherein the result data is provided by the second die in response to receiving the test data.

14. The circuit of claim 12, wherein the first die comprises a first multiplexer and a second multiplexer, and the second die comprises a third multiplexer and a fourth multiplexer.

15. The circuit of claim 14, wherein, during the first operation stage, the first multiplexer and the second multiplexer are configured to select a first clock and provide the first clock to a first interface circuit and a second interface circuit, respectively, and the third multiplexer and the fourth multiplexer are configured to select the first clock and provide the first clock to a third interface circuit and a fourth interface circuit, respectively.

16. The circuit of claim 15, wherein, during the second operation stage, the second multiplexer is configured to select a second clock and provide the second clock to the second interface circuit then to the fourth interface circuit through a first interconnect of the at least one interconnect, the third multiplexer is configured to select the second clock received through a second interconnect of the at least one interconnect and provide the second clock to the third interface circuit then to the first interface circuit through the first interconnect, and the fourth multiplexer is configured to select the second clock received also through the second interconnect and provide the second clock to the fourth interface circuit.

17. The circuit of claim 12, wherein the first die and the second die are laterally or vertically arranged with respect to each other.

18. A method, comprising:
loading, based on a first frequency, a first logic value and a second logic value to a first interface circuit of a first die and a second interface circuit of a second die, respectively;
capturing, during a first pulse with a second frequency, a third logic value presented by the second die;
capturing, during a second pulse with the second frequency, a fourth logic value presented by the second die; and
determining whether an interconnect coupling the first interface circuit to the second interface circuit has malfunction based on the fourth logic value;
wherein the second frequency is substantially higher than the first frequency.

19. The method of claim 18, wherein the first die and the second die are laterally arranged with respect to each other.

20. The method of claim 18, wherein the first die and the second die are vertically arranged with respect to each other.
